(19) United States
(12) Patent Application Publication
(10) Pub. No.: US 2008/0044166 A1
(43) Pub. Date: Feb. 21, 2008

(54) VAPORIZER APPARATUS WITH AUTOMATIC FEEDING OF A WIRE INTO A CRUCIBLE

(75) Inventors: Ulrich Englert, Heigenbruecken (DE); Guido Hattendorf, Brachttal (DE); Michael Schafer, Altenstadt (DE)

Correspondence Address: PATTERSON & SHERIDAN, L.L.P., 3040 POST OAK BOULEVARD, SUITE 1500, HOUSTON, TX, 77056, US

(73) Assignee: APPLIED MATERIALS GmbH & CO. KG, Alzenau (DE)

(21) Appl. No.: 11/837,420

(22) Filed: Aug. 10, 2007

(30) Foreign Application Priority Data
Aug. 16, 2006 (EP) 06 119 007.0

(51) Int. Cl. C23C 14/24

(52) U.S. Cl. 392/389

(57) ABSTRACT

Embodiments of the present invention relate to a vaporizer apparatus with automatic feeding of a wire into a crucible. All of the parts of this vaporizer apparatus are mounted on only one carrier plate, such that a rapid mounting or dismounting, for example in clean rooms, is possible without particles being generated. In addition, a helical heating element is encompassed by a protective tube such that this helical heating element does not come into contact with the material to be vaporized.

### BACKGROUND OF THE INVENTION

1. Field of the Invention

Embodiments of the present invention generally relate to a vaporizer apparatus.

2. Description of the Related Art

Modern flat picture screens comprise liquid crystal elements or plasma elements for the reproduction of pictures or characters. More recently, flat picture screens are also produced which include organic light-emitting diodes (OLEDs) as color pixels.

In the production of an OLED flat screen, first onto a glass plate an ITO (Indium Tin Oxide) layer is applied which is permeable to light yet electrically conducting. Onto this layer the OLED material is subsequently vapor-deposited, onto which as the next layer a metal can be vapor-deposited.

In order to generate the vapor, vaporizers are provided which heat the material to be vaporized. However, conventional vaporizers have some disadvantages.

The heaters for vaporizing metals are, as a rule, mounted around a vaporizer tube (DE 38 17 513 C2, DE 101 28 091 C1). Of disadvantage in the case of heaters located outside the vaporizer tube is that they have large thermal losses. In the coating of OLEDs with metals, where for the vaporization of the metals temperatures of more than 1200° C. must be generated, such heaters affect the OLEDs negatively due to their thermal radiation.

A conventional vaporization apparatus is described in U.S. Pat. No. 5,157,240. The vaporization apparatus includes on the inner wall of its vaporizers a resistance heater in the form of a graphite layer. However the material to be vaporized cannot be fed continuously to the crucible utilized in the vaporization apparatus.

Vaporizers to which the material to be vaporized can be fed automatically and in the form of wires are described in U.S. Pat. No. 3,467,058, and GB 1 203 069. In the case of these vaporizers the material to be coated must be disposed parallel to the surface of the material to be vaporized.

A vaporizer apparatus with a feeding of a wire into a crucible is described in DD 76 820 A. However, this apparatus does not include its own wire feed housing. The driving arrangement, additionally, is not disposed on a carrier plate.

A vaporizer apparatus with a wire feeding is described in FR 1 369 360 A, wherein a wire is introduced into a crucible. However, this apparatus does not include a wire feed housing which is detachably flanged onto one side of a carrier plate.

A vaporizer apparatus with an automatic feeding of a wire and with a crucible is described in U.S. Pat. No. 5,321,792 A. However, a separately flanged-on housing for the feeding of a wire, i.e. a wire feed housing, is herein not provided.

Therefore, there is a need for an improved vaporizer apparatus.

### SUMMARY OF THE INVENTION

Embodiments of the present invention generally provide a vaporizer apparatus with automatic feeding of a wire into a crucible.

One embodiment of the present invention provides a vaporizer apparatus with automatic feeding of a wire into a crucible and with a carrier plate comprising a wire feed housing detachably flanged onto a first side of the carrier plate, a linear vaporizer disposed above the crucible, the linear vaporizer being detachably flanged onto a second side of the carrier plate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 schematically illustrates a perspective view of a linear vaporizer in accordance with one embodiment of the present invention.

FIG. 2 schematically illustrates a side view of the vaporizer according to FIG. 1, a portion of the side being broken open.

FIG. 3 schematically illustrates an exploded representation of the vaporizer according to FIG. 1.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention provide a compact vaporizer, preferably for metals, with a continuous material feeding for the coating of substrates which are also guided vertically.

Embodiments of the present invention consequently relate to a vaporizer apparatus with automatic feeding of a wire into a crucible. All parts of this vaporizer apparatus are mounted on only one carrier plate, such that rapid mounting or dismounting, for example in clean rooms, is possible without particles being generated. In addition, a heating coil is encompassed by a protective tube such that this heating coil does not come into contact with the material to be vaporized.

The advantage attained with embodiments of the present invention comprises in particular that the surface of the heating elements does not come into contact with potentially aggressive metal vapor. The complete vaporizer unit can be disposed on a flange and be readily mounted on a coating unit or be dismounted from it. Since the vaporizer unit is thermally encapsulated, it marginally radiates heat into the environs.

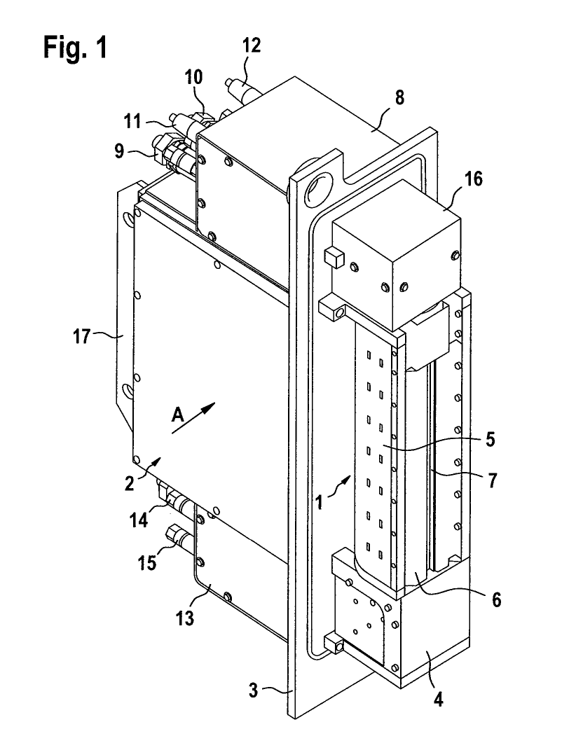

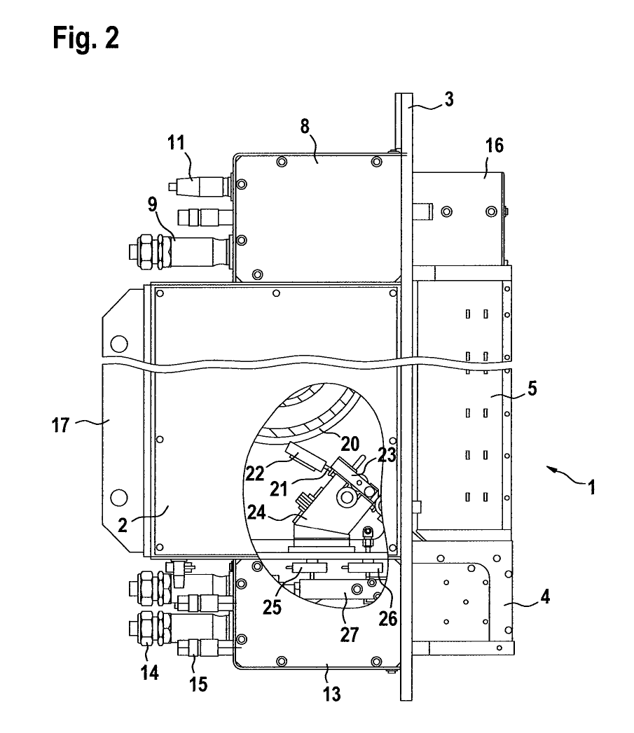

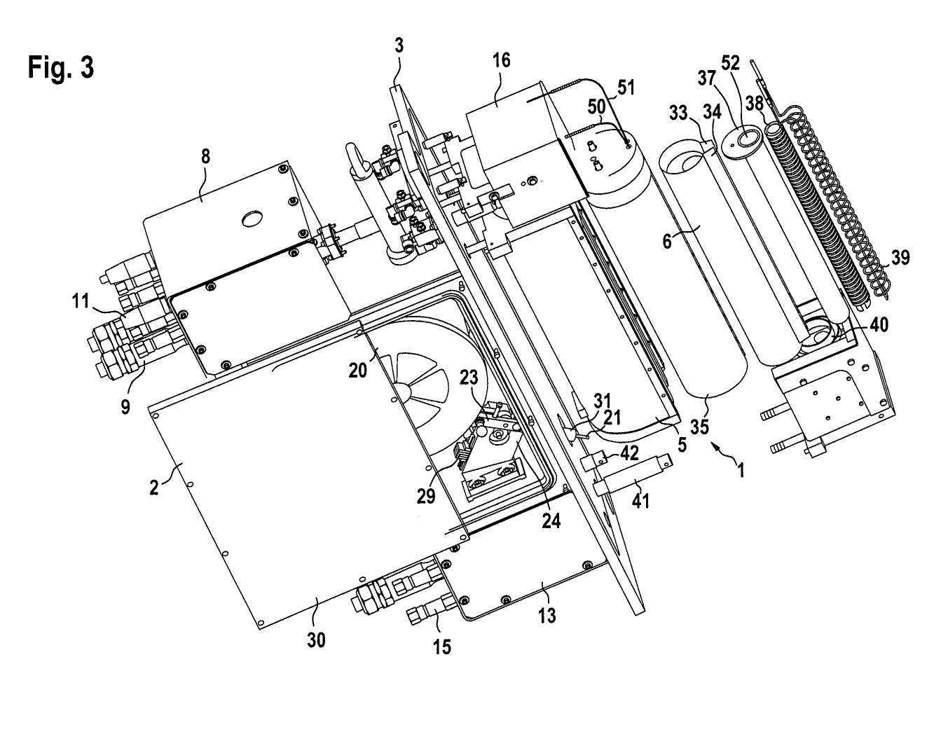

An embodiment example of the invention is shown in FIGS. 1-3 and will be described in the following in further detail. FIG. 1 schematically illustrates a perspective view of a linear vaporizer. FIG. 2 schematically illustrates a side view of the vaporizer according to FIG. 1, a portion of the side being broken open. FIG. 3 schematically illustrates an exploded representation of the vaporizer according to FIG. 1.

FIG. 1 shows a vaporizer 1 with a wire feed housing 2. Vaporizer 1 and wire feed housing 2 are connected with one another via a carrier plate 3. The vaporizer 1 comprises a melting chamber 4, above which a distributor housing 5 is located, which also serves for cooling purposes. The distributor housing 5 is curved in the shape of a U on its backside and shows at its front opening a distributor tube 6, which includes a linear distributor slot 7. On the top side of the wire feed housing 2 is disposed a box 8, which includes quick disconnect couplings 9, 10 and plugs 11, 12. On the underside of the wire feed housing 2 is likewise located a box 13 with quick disconnect couplings 14, 15. Above the vaporizer 1 is provided a further box 16, in which are located electrical and electronic parts. By 17 is denoted a flange, which is connected with the wire feed housing 2 and serves for the connection to arrangements not shown in FIG. 1.

FIG. 2 shows a plan view A (cf. FIG. 1) onto one side of vaporizer 1 with the wire feed housing 2. Through the break-open of the wire feed housing 2 is evident a supply reel 20 on which wire is wound. This wire 21 reaches from the supply reel 20 via a wire guide 22 into a wire feed module 24, which includes a further wire guide 23, and from here into the melting chamber 4. Consequently, the vacuum of the melting chamber 4 is not broken. The driving means for the movement of the wire 21 is not further shown.

FIG. 3 once again shows the vaporizer 1 in an exploded view, in which the individual structural elements of the vaporizer 1 are visible. A side wall 30 of the wire feed housing 2 is shifted slightly to the side such that the supply reel 20 is evident again, from which the wire 21 is unwound. It can be seen that the wire 21 is guided via the wire feed module 24 and through a tubule 31 from the wire feed housing 2 into the vaporizer 1. Exploded from the distributor 5, which is cooled, are: a support tube 35 for thermal insulation, a vaporizer tube 6 with vapor guide plates 33, 34, a support and holding ring 37 for a protective tube 52, a carrier 38 for a helical heating element and the helical heating element 39 itself. 40 denotes a crucible which is electrically insulated and cooled.

Projections 41, 42 on the wire feed housing 2 serve as fasteners and for the power supply.

Into the support tube 35 lead two electrical lines 50, 51 which serve for heating the vaporizer tube 6 and are connected to the helical heating element 39.

In FIG. 2, which shows the vaporizer 1 with the wire feed housing 2 in the assembled state, is evident that the wire 21 is continuously fed to the vaporizer 1 without the vacuum being broken. 25 and 26 denote clamping rings for feeding through the cooling means, while the structural part 27 involves a conductor bar.

The entire apparatus according to FIG. 1 is mounted on only one carrier plate, which permits rapid introducing into and removing from a clean room without spurious particles being generated. Through an independent mounting of the vaporizer 1 and of the wire feed housing 2 on the carrier plate 3, scaling for future substrate sizes independently of the parts is also possible.

As FIG. 3 shows, the electrically heatable helical heating element 39—supported by carrier 38—is located in the vaporizer tube.

In the assembled state the helical heating element 39 encompasses the carrier 38. Carrier 38 and helical heating element 39 are placed into a protective tube 52 for the helical heating element 39, which, in turn, is encompassed by a support and holding ring 37 for the protective tube 52. All of these structural parts are introduced into the vaporizer tube 6, which includes opening 7 with the vapor guide plates 33, 34. The vaporizer tube 6 including its contents is subsequently placed into the support tube 35 for thermal insulation, which, in turn, is encompassed by the cooling housing 5. By 29 is denoted a terminal array for the driving of the wire feeding by an electric motor.

In the assembled state crucible 40 with insulation and cooling is located directly on fasteners 41, 42 with power supply and consequently beneath the vaporizer tube 6 encompassed by the cooling means 5. In this position the wire 21 comprised of the vaporization material can also be fed directly from the supply reel 20 to the vaporizer crucible 40. The wire feed module 24 and the supply reel 20 are located in a vacuum-tight housing, which, using vacuum technique, is connected with the vaporizer tube 6 and the process chamber.

The protective tube 52 for the helical heating element 39 serves to prevent the embrittlement of this heating element 39 through aggressive materials, for example vaporized aluminum.

The individual components of the apparatus 1, 2 are constructionally disposed and laid out such that they can be exchanged independently of one another without other components needing to be disassembled. Thus, for example, the vaporizer crucible 40 with the cooling means encompassing it is so disposed in the melting chamber 4 that it can be readily replaced.

While the foregoing is directed to embodiments of the present invention, other and further embodiments of the invention may be devised without departing from the basic scope thereof, and the scope thereof is determined by the claims that follow.

What is claimed is:

1. A vaporizer apparatus with automatic feeding of a wire into a crucible and with a carrier plate, comprising:
a wire feed housing detachably flanged onto a first side of the carrier plate;
a linear vaporizer disposed above the crucible, the linear vaporizer being detachably flanged onto a second side of the carrier plate.

2. The vaporizer apparatus as claimed in claim 1, wherein the wire feed housing comprises a winding reel for the wire.

3. The vaporizer apparatus as claimed in claim 1, wherein an aperture is formed in the carrier plate, the wire is guided to the crucible through the aperture.

4. The vaporizer apparatus as claimed in claim 1, wherein the linear vaporizer comprises a support tube in which a distributor tube with a helical heating element is provided.

5. The vaporizer apparatus as claimed in claim 4, wherein the helical heating element is looped about a carrier.

6. The vaporizer apparatus as claimed in claim 4, wherein the helical heating element is disposed in a protective tube.

7. The vaporizer apparatus as claimed in claim 6, wherein the protective tube is provided at least on one end with a support ring.

8. The vaporizer apparatus as claimed in claim 5, wherein the helical heating element and the carrier are disposed in a protective tube.

9. The vaporizer apparatus as claimed in claim 8, wherein the protective tube is provided at least on one end with a support ring.
